(19) United States
(12) Patent Application Publication
(10) Pub. No.: US 2024/0067480 A1
(43) Pub. Date: Feb. 29, 2024

(54) VACUUM TREATMENT APPARATUS AND VACUUM TREATMENT METHOD

(71) Applicant: ULVAC, INC., Chigasaki-shi (JP)

(72) Inventors: Yoshiaki FUKUDA, Chigasaki-shi (JP); Shunsuke SASAKI, Chigasaki-shi (JP); Takahito KIMOTO, Chigasaki-shi (JP); Michinari SUGIMURA, Chigasaki-shi (JP)

(21) Appl. No.: 18/361,293

(22) Filed: Jul. 28, 2023

(30) Foreign Application Priority Data
Aug. 24, 2022 (JP) 2022-133319

(51) Int. Cl. B65H 18/20; B65H 23/038

(52) U.S. Cl. CPC B65H 18/20; B65H 23/038; B65H 2404/1362; B65H 2553/27

(57) ABSTRACT

In a present vacuum treatment apparatus, a controller controls an auxiliary roller, a thermometer, a power source, and a temperature control mechanism, in which the controller detects a temperature of a base material wound and conveyed by a main roller, starts film deposition to form a film deposition material on the base material when the temperature of the base material is in a film deposition temperature range, adjusts, when the temperature of the base material is out of a threshold range after starting film deposition on the base material, the temperature of the main roller so that the temperature of the base material falls within the threshold range and adjusts an adhesion force between the main roller and the base material, and continues the film deposition of the film deposition material on the base material with the temperature of the base material in the film deposition temperature range.

### CROSS REFERENCE TO RELATED APPLICATIONS

This application claims the benefit of Japanese Priority Patent Application JP 2022-133319 filed Aug. 24, 2022, the entire contents of which are incorporated herein by reference.

### BACKGROUND

The present invention relates to a vacuum treatment apparatus and a vacuum treatment method.

There is known a film deposition system using roll-to-roll processing that forms a film on an elongated film deposition target base material (band-like film) (hereinafter, referred to as a base material) while winding the base material through a main roller in a pressure-reduced atmosphere. In such a film deposition system, a deposition source is disposed facing the film deposition target base material wound and conveyed by the main roller for depositing a film deposition material fed from the deposition source on the film deposition target base material (e.g., see Japanese Patent Application Laid-open No. 2009-019246 (hereinafter, referred to as Patent Literature 1)). Accordingly, the film is formed on the film deposition target base material wound and conveyed by the main roller. Moreover, in such a film deposition system, the main roller is kept at a constant temperature by being fed with a medium having a controlled temperature.

### SUMMARY

However, in a case of controlling the temperature of the main roller only with the temperature of the medium fed to the main roller, the temperature of the main roller may not immediately become a predetermined temperature due to a difference in heat capacity between the medium and the main roller even by setting the temperature of the medium to be the predetermined temperature if the temperature of the base material wound and conveyed by the main roller changes due to some external factor. Accordingly, it takes a certain time for the main roller to reach a desired temperature and the base material wound and conveyed by the main roller can be deformed (e.g., wrinkled).

In view of the above-mentioned circumstances, it is desirable to provide a vacuum treatment apparatus and a vacuum treatment method that form a base material with a highly reliable film formed thereon by reducing deformation of the base material wound and conveyed by a main roller when the temperature of the base material wound and conveyed by the main roller changes.

### Solution to Problem

According to an embodiment of the present invention, a vacuum treatment apparatus includes a wind-off roller, a wind roller, a main roller, a deposition source, an auxiliary roller, a thermometer, a power source, a temperature control mechanism, and a controller.

The wind-off roller pays out a base material having a film deposition surface and a non-film deposition surface opposite to the film deposition surface.

The wind roller winds the base material.

The main roller is provided between the wind-off roller and the wind roller in a conveying direction in which the base material is conveyed, has an outer circumferential surface that is held in contact with the non-film deposition surface, and winds and conveys the base material.

The deposition source faces the outer circumferential surface of the main roller that is held in contact with the non-film deposition surface.

The auxiliary roller is provided at least either between the wind-off roller and the main roller or between the wind roller and the main roller in the conveying direction, guides conveyance of the base material, and adjusts a tensile force of the base material wound and conveyed by the main roller.

The thermometer measures a temperature of the base material wound and conveyed by the main roller.

The power source applies a bias potential to the main roller.

The temperature control mechanism adjusts a temperature of the main roller.

The controller controls the auxiliary roller, the thermometer, the power source, and the temperature control mechanism.

The controller
detects the temperature of the base material wound and conveyed by the main roller,
starts film deposition to form a film deposition material on the base material when the temperature of the base material is in a film deposition temperature range,
adjusts, when the temperature of the base material is out of a threshold range after starting film deposition on the base material, the temperature of the main roller so that the temperature of the base material falls within the threshold range and adjusts an adhesion force between the main roller and the base material, and
continues the film deposition of the film deposition material on the base material with the temperature of the base material in the film deposition temperature range.

In accordance with such a vacuum treatment apparatus, deformation of the base material wound and conveyed by the main roller is further reduced when the temperature of the base material wound and conveyed by the main roller changes, and a base material with a highly reliable film formed thereon is formed.

In the above-mentioned vacuum treatment apparatus, when the controller determines that the temperature of the main roller is stabilized after the temperature of the base material falls within the threshold range, the controller may switch from control to adjust the temperature of the base material with temperature adjustment of the main roller and the adhesion force between the main roller and the base material to control to adjust the temperature of the base material with the temperature of the main roller.

In accordance with such a vacuum treatment apparatus, deformation of the base material wound and conveyed by the main roller is further reduced when the temperature of the base material wound and conveyed by the main roller changes, and a base material with a highly reliable film formed thereon is formed.

In the above-mentioned vacuum treatment apparatus, the controller may control the adhesion force with the tensile force of the base material wound and conveyed by the main roller or with an electrostatic force acting between the main roller and the base material.

In accordance with such a vacuum treatment apparatus, deformation of the base material wound and conveyed by the main roller is reduced when the temperature of the base material wound and conveyed by the main roller changes, and a base material with a highly reliable film formed thereon is formed.

According to an embodiment of the present invention, a vacuum treatment method includes:
by use of the above-mentioned vacuum treatment apparatus,
detecting the temperature of the base material wound and conveyed by the main roller;
starting film deposition to form a film deposition material on the base material when the temperature of the base material is in a film deposition temperature range;
adjusting, when the temperature of the base material is out of a threshold range after starting film deposition on the base material, the temperature of the main roller so that the temperature of the base material falls within the threshold range and adjusts an adhesion force between the main roller and the base material; and
continuing the film deposition of the film deposition material on the base material with the temperature of the base material in the film deposition temperature range.

In accordance with such a vacuum treatment method, deformation of the base material wound and conveyed by the main roller is reduced when the temperature of the base material wound and conveyed by the main roller changes, and a base material with a highly reliable film formed thereon is formed.

In the above-mentioned vacuum treatment method, when the temperature of the main roller is stabilized after the temperature of the base material falls within the threshold range, control to adjust the temperature of the base material with temperature adjustment of the main roller and the adhesion force between the main roller and the base material may be switched to control to adjust the temperature of the base material with the temperature of the main roller.

In accordance with such a vacuum treatment method, deformation of the base material wound and conveyed by the main roller is further reduced when the temperature of the base material wound and conveyed by the main roller changes, and a base material with a highly reliable film formed thereon is formed.

In the above-mentioned vacuum treatment method, the adhesion force may be controlled with the tensile force of the base material wound and conveyed by the main roller or with an electrostatic force acting between the main roller and the base material.

In accordance with such a vacuum treatment method, deformation of the base material wound and conveyed by the main roller is further reduced when the temperature of the base material wound and conveyed by the main roller changes, and a base material with a highly reliable film formed thereon is formed.

As described above, in accordance with the present invention, a vacuum treatment apparatus and a vacuum treatment method that form a base material with a highly reliable film formed thereon by reducing deformation of the base material wound and conveyed by a main roller when the temperature of the base material wound and conveyed by the main roller changes are provided.

### BRIEF DESCRIPTION OF DRAWINGS

FIG. 1 is a schematic diagram showing an example of a vacuum treatment apparatus according to the present embodiment.

FIG. 2 is a flowchart showing an example of a vacuum treatment method according to the present embodiment.

### DETAILED DESCRIPTION OF EMBODIMENTS

Hereinafter, embodiments of the present invention will be described with reference to the drawings. Moreover, the same components or components having the same functions will be sometimes denoted by the same reference signs and duplicated descriptions of the components will be sometimes omitted as appropriate. In addition, numeric values described below are exemplary and not limitative.

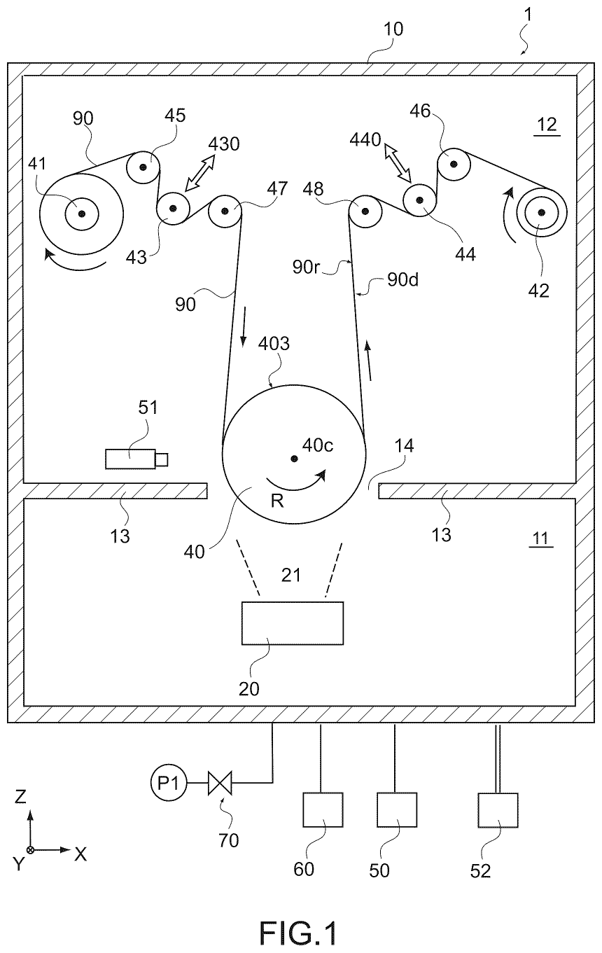

FIG. 1 is a schematic diagram showing an example of a vacuum treatment apparatus according to the present embodiment. A vacuum treatment apparatus 1 illustrated in FIG. 1 is a vacuum treatment apparatus using roll-to-roll processing that forms a film on an elongated base material 90 under a condition of a pressure-reduced atmosphere below an atmospheric pressure. In FIG. 1, a direction of a center axis 40c of a main roller 40 is a Y-axis direction and a direction from a deposition source 20 to the main roller 40 is a Z-axis direction. A direction orthogonal to the Y-axis direction and the Z-axis direction is an X-axis direction.

The vacuum treatment apparatus 1 includes a vacuum chamber 10, the deposition source 20, the main roller 40, a wind-off roller 41, a wind roller 42, an auxiliary roller 45, an auxiliary roller 46, an auxiliary roller 47, an auxiliary roller 48, a bias power source 50, a thermometer 51, a temperature control mechanism 52, a controller 60, and a gas discharge mechanism 70. The vacuum treatment apparatus 1 may include an image treatment apparatus that detects a wrinkle made in the base material 90. Moreover, the auxiliary roller may be called guide roller.

The vacuum treatment apparatus 1 includes a rotational driving mechanism (not shown) that rotates each of the main roller 40, the wind-off roller 41, and the wind roller 42. Rotational driving mechanisms may be provided in the auxiliary rollers depending on needs. The vacuum treatment apparatus 1 includes a moving mechanism (not shown) for moving an auxiliary roller 43 in the direction of the double arrow 430 and also includes a moving mechanism (not shown) for moving an auxiliary roller 44 in the direction of the double arrow 440. Moreover, the vacuum treatment apparatus 1 may include a gas feeding mechanism for feeding a gas into the vacuum chamber 10.

In the vacuum treatment apparatus 1, the base material 90 is a base material for film deposition. The base material 90 is conveyed to the main roller 40 through the auxiliary roller 45, the auxiliary roller 43, and the auxiliary roller 47 from the wind-off roller 41 inside the vacuum chamber 10. In addition, the base material 90 is conveyed to the wind roller 42 through the auxiliary roller 48, the auxiliary roller 44, and the auxiliary roller 46 from the main roller 40 at a predetermined conveying velocity. For example, the base material 90 is wound by the wind-off roller 41 and is paid out to the main roller 40 from the wind-off roller 41 through the auxiliary roller 45, the auxiliary roller 43, and the auxiliary roller 47. The base material 90 paid out to the main roller 40 from the wind-off roller 41 is wound and conveyed by the main roller 40 and is wound by the wind roller 42 through the auxiliary roller 48, the auxiliary roller 44, and the auxiliary roller 46. The film deposition material fed from the deposition source 20 is deposited on the base material 90 wound and conveyed by the main roller 40 and a film is formed on the base material 90. In the present embodiment, a direction along a direction in which the base material 90 is conveyed is set as a conveying direction.

The vacuum chamber 10 has a hermetically-sealed structure. The vacuum chamber 10 can be kept in a predetermined pressure-reduced atmosphere through the gas discharge mechanism 70 with the vacuum pump P1. The vacuum treatment apparatus 1 includes, for example, a film deposition chamber 11 and a treatment chamber 12. The film deposition chamber 11 and the treatment chamber 12 are partitioned by a partition wall 13. The vacuum chamber 10 houses the deposition source 20, the main roller 40, the wind-off roller 41, the wind roller 42, the auxiliary roller 48, the auxiliary roller 44, the auxiliary roller 46, the auxiliary roller 48, the auxiliary roller 44, the auxiliary roller 46, and the thermometer 51 in the example in FIG. 1.

The partition wall 13 has an opening 14 so that a part of the main roller 40 can enter the film deposition chamber 11 from the treatment chamber 12 without contact between the main roller and the partition wall 13. Moreover, the presence of the opening 14 in the partition wall 13 makes a clearance between the main roller 40 and the partition wall 13. The base material 90 wound and conveyed by the main roller 40 passes between the treatment chamber 12 and the film deposition chamber 11 through this clearance.

The deposition source 20 is provided in the film deposition chamber 11. The deposition source 20 includes an evaporation source, for example. The deposition source 20 faces an outer circumferential surface 403 of the main roller 40. The deposition source 20 includes a resistance heating evaporation source, an induction heating evaporation source, an electron-beam heating evaporation source, and other evaporation sources. A film deposition material, e.g., an alkaline metal or alkaline earth metal is evaporated toward the main roller 40 from the deposition source 20. The film deposition material includes alkaline metals such as Li and Na and alkaline earth metals such as Mg and Ca, for example. A film formed on the base material 90 has a thickness of 20 μm or less. When a Li film is used as the film, this film is used for a negative electrode of a lithium battery, for example.

The film deposition chamber 11 is connected to the gas discharge mechanism 70. The film deposition chamber 11 maintains a reduced-pressure state through the gas discharge mechanism 70. The treatment chamber 12 is in communication with the film deposition chamber 11 through the opening 14. The treatment chamber 12 is evacuated through the opening 14 when the film deposition chamber 11 is evacuated. In the example in FIG. 1, the treatment chamber 12 is not connected to the gas discharge mechanism 70. Accordingly, when the film deposition chamber 11 is evacuated, a pressure difference is generated where the pressure of the treatment chamber 12 is higher than the pressure of the film deposition chamber 11. This pressure difference inhibits a vapor flow 21 (film deposition material) from the deposition source 20 from entering the treatment chamber 12 through the opening 14. It should be noted that the treatment chamber 12 is evacuated through the gas discharge mechanism depending on needs.

The main roller 40 is provided between the wind-off roller 41 and the wind roller 42 in the direction in which the base material 90 is conveyed. A part of the main roller 40 is arranged in the film deposition chamber 11 and the other part is arranged in the treatment chamber 12. The main roller 40 faces the deposition source 20. The main roller 40 has the outer circumferential surface 403 that is held in contact with a non-film deposition surface (back surface) 90r of the base material 90. In the example in FIG. 1, the main roller 40 rotates counter-clockwise. In the present embodiment, the direction in which the main roller 40 rotates will be referred to as a direction of rotation R.

The main roller 40 contains a metal material such as stainless steel, iron, and aluminum and has a tubular shape. For example, a temperature control mechanism (not shown) may be provided inside the main roller 40. A width of the main roller 40 in the direction of the center axis 40c is set to be larger than a width of the base material 90. The main roller 40 winds and conveys the base material 90 unwound by the wind-off roller 41 and pays out the base material 90 with the film formed thereon toward the wind roller 42.

The wind-off roller 41 is provided in the treatment chamber 12. The base material 90 is wound around the wind-off roller 41 in advance. The wind-off roller 41 rotates about its center axis in the arrow direction at a predetermined rotation velocity. The wind-off roller 41 pays out the base material 90 toward the main roller 40.

The wind roller 42 is provided in the treatment chamber 12. The wind roller 42 rotates about its center axis in the arrow direction at a predetermined rotation velocity. The wind roller 42 winds the base material 90 wound and conveyed by the main roller 40 and has the film deposition material deposited thereon.

A set of the auxiliary rollers 45, 43, and 47 is provided between the wind-off roller 41 and the main roller 40 in the conveying direction. The auxiliary roller 45 is provided between the wind-off roller 41 and the auxiliary roller 43 in the conveying direction and guides conveyance of the base material 90. The auxiliary roller 43 is provided between the auxiliary roller 45 and the auxiliary roller 47 in the conveying direction and guides conveyance of the base material 90. The auxiliary roller 47 is provided between the auxiliary roller 43 and the main roller 40 in the conveying direction and guides conveyance of the base material 90.

The auxiliary roller 43 of the auxiliary rollers 45, 43, and 47 is movable in the direction of the double arrow 430 through the moving mechanism. Accordingly, the tensile force of the base material 90 wound and conveyed by the main roller 40 can be adjusted. For example, when the auxiliary roller 43 moves closer to the film deposition chamber 11, a pulling force acts on the base material 90 wound and conveyed by the main roller 40. The tensile force of the base material 90 wound and conveyed by the main roller 40 accordingly increases. In other words, when the auxiliary roller 43 moves closer to the film deposition chamber 11, an adhesion force between the base material 90 and the main roller 40 increases and thermal conductivity between the base material 90 and the main roller 40 increases.

On the other hand, when the auxiliary roller 43 moves away from the film deposition chamber 11, the tensile force of the base material 90 wound and conveyed by the main roller 40 decreases, and the tensile force of the base material 90 wound and conveyed by the main roller 40 accordingly decreases. In other words, when the auxiliary roller 43 moves away from the film deposition chamber 11, the adhesion force between the base material 90 and the main roller 40 decreases and the thermal conductivity between the base material 90 and the main roller 40 decreases. The auxiliary roller 43 can also be called tensile force control roller other than the guide roller.

Moreover, a set of auxiliary rollers 48, 44, and 46 is provided between the wind roller 42 and the main roller 40 in the conveying direction. The auxiliary roller 48 is provided between the main roller 40 and the auxiliary roller 44 in the conveying direction and guides conveyance of the base material 90. The auxiliary roller 44 is provided between the auxiliary roller 48 and the auxiliary roller 46 in the conveying direction and guides conveyance of the base material 90. The auxiliary roller 46 is provided between the auxiliary roller 44 and the wind roller 42 in the conveying direction and guides conveyance of the base material 90.

The auxiliary roller 44 of the auxiliary rollers 48, 44, and 46 is movable in the direction of the double arrow 440 through the moving mechanism. Accordingly, the tensile force of the base material 90 wound and conveyed by the main roller 40 can also be adjusted by the auxiliary roller 44. For example, when the auxiliary roller 44 moves closer to the film deposition chamber 11, a pulling force acts on the base material 90 wound and conveyed by the main roller 40, and the tensile force of the base material 90 wound and conveyed by the main roller 40 accordingly increases. In other words, when the auxiliary roller 44 moves closer to the film deposition chamber 11, the adhesion force between the base material 90 and the main roller 40 increases and the thermal conductivity between the base material 90 and the main roller 40 increases.

On the other hand, when the auxiliary roller 44 moves away from the film deposition chamber 11, the tensile force of the base material 90 wound and conveyed by the main roller 40 decreases, and the tensile force of the base material 90 wound and conveyed by the main roller 40 accordingly decreases. In other words, when the auxiliary roller 44 moves away from the film deposition chamber 11, the adhesion force between the base material 90 and the main roller 40 decreases and the thermal conductivity between the base material 90 and the main roller 40 decreases. The auxiliary roller 44 can also be called tensile force control roller other than the guide roller.

Either the set of the auxiliary rollers 43, 45, and 47 or the set of the auxiliary rollers 44, 46, and 48 may be removed as appropriate in the vacuum treatment apparatus 1. That is, the auxiliary roller controlled by the moving mechanism is provided at least either between the wind-off roller 41 and the main roller 40 or between the wind roller 42 and the main roller 40 in the conveying direction in the vacuum treatment apparatus 1.

The base material 90 includes a film deposition surface 90d and a non-film deposition surface 90r opposite to the film deposition surface 90d. The film deposition surface 90d faces the deposition source 20. The vapor flow 21 fed from the deposition source 20 is deposited on the film deposition surface 90d and a film is formed on the film deposition surface 90d of the base material 90 on the main roller 40. The non-film deposition surface 90r is held in contact with the outer circumferential surface 403 of the main roller 40.

The base material 90 is a sheet-like elongated film (with a thickness of 50 μm or less). The base material 90 is flexible. For example, the base material 90 is a band-like film constituted by an oriented polypropylene (OPP) resin, a polyethylene terephthalate (PET) resin, a polyphenylene sulfide (PPS) resin, and/or a polyimide (PI) resin. The base material 90 may be a band-like metal foil constituted by Cu, Al, Ni, and/or SUS steel, for example.

The bias power source 50 applies a bias potential (e.g., a positive potential) to the main roller 40. The bias power source 50 is provided outside the vacuum chamber 10. Applying the bias potential to the main roller 40 causes an electrostatic force to act between the base material 90 and the main roller. Accordingly, an electrostatic adhesion force (hereinafter, simply referred to as an adhesion force) acts between the main roller 40 and the base material 90 when the main roller 40 winds and conveys the base materials 90 and 95, and it suppresses deviation and wrinkling of the base material 90 on the main roller 40.

Moreover, adjusting the bias potential applied to the main roller 40 from the bias power source 50 can change the adhesion force between the base material 90 and the main roller 40. Accordingly, the thermal conductivity between the base material 90 and the main roller 40 can be adjusted. For example, increasing the adhesion force between the base material 90 and the main roller 40 increases the thermal conductivity between the base material 90 and the main roller 40 and lowering the adhesion force between the base material 90 and the main roller 40 lowers the thermal conductivity between the base material 90 and the main roller 40. It should be noted that the vacuum chamber 10, the wind-off roller 41, the wind roller 42, the auxiliary rollers 45, 43, and 47, and the auxiliary rollers 48, 44, and 46 are set at a ground potential.

The thermometer 51 measures a temperature of the base material 90 wound and conveyed by the main roller 40. The thermometer 51 measures a temperature of the base material 90 after it is held in contact with the main roller 40. The thermometer 51 is a contactless thermometer not in contact with the base material 90 and includes an infrared sensor, for example. The thermometer 51 may be placed outside the vacuum chamber 10. In this case, the thermometer 51 measures a temperature of the base material 90 via a window provided in the vacuum chamber 10. Calibration curves of the temperature of the main roller 40 and the temperature of the base material 90 are determined in advance before the start of film deposition. The controller 60 stores the calibration curves.

The temperature control mechanism 52 adjusts the temperature of the main roller 40 with a medium. The temperature control mechanism 52 is provided outside the vacuum chamber 10. For example, a medium set at a predetermined temperature is fed to the main roller 40 from the temperature control mechanism 52 through a piping (not shown) and the medium from the main roller 40 returns to the temperature control mechanism 52 through another piping (not shown). Repeating this operation adjusts the temperature of the main roller 40 to be the predetermined temperature. Calibration curves of the outer circumferential surface 403 of the temperature of the main roller 40 and the temperature of the medium are determined in advance before the start of film deposition. The controller 60 stores the calibration curves. The temperature of the base material 90 held in contact with the main roller 40 can be set with the set temperature of the medium by combining the calibration curves of the temperature of the main roller 40 and the temperature of the base material 90 and the calibration curves of the outer circumferential surface 403 of the temperature of the main roller 40 and the temperature of the medium.

The controller 60 controls the deposition source 20, the main roller 40, the wind-off roller 41, the wind roller 42, the auxiliary rollers 43 and 44, the thermometer 51, the bias power source 50, and the temperature control mechanism 52. The controller 60 is provided outside the vacuum chamber 10. For example, the controller 60 controls the deposition source 20 and controls whether or not to perform film deposition on the base material 90. The controller 60 controls the main roller 40, the wind-off roller 41, and the wind roller 42 and controls the conveying velocity of the base material 90. The controller 60 controls the position of each of the auxiliary rollers 43 and 44 via the moving mechanism and controls the adhesion force between the base material 90 and the main roller 40. Moreover, the controller 60 controls the bias potential applied to the main roller via the bias power source 50 and controls the adhesion force between the base material 90 and the main roller 40. Moreover, the controller 60 controls the temperature of the medium fed to the main roller 40 via the temperature control mechanism 52 and controls the temperature of the main roller 40 or the temperature of the base material 90. Moreover, the controller 60 detects a temperature of the base material 90 from the thermometer 51 and controls each of the auxiliary rollers 43 and 44, the bias power source 50, and the temperature control mechanism 52.

A deposition method of depositing the film deposition material from the deposition source on the film deposition surface 90d of the base material 90 by the use of the vacuum treatment apparatus 1 will be described. The controller 60 automatically performs the deposition method described below.

For example, the controller 60 detects a temperature of the base material 90 wound and conveyed by the main roller 40 through the thermometer 51. The controller 60 starts film deposition to form the film deposition material on the base material 90 when the temperature of the base material 90 falls within a film deposition temperature range. When the temperature of the base material 90 is out of a threshold range (threshold range<film deposition temperature range) after the start of film deposition on the base material 90, the controller 60 adjusts the temperature of the main roller 40 so that the temperature of the base material 90 falls within the threshold range and adjusts the adhesion force between the main roller 40 and the base material 90. The controller 60 continues the film deposition of the film deposition material on the base material 90 with the temperature of the base material 90 in the film deposition temperature range.

Here, when the controller 60 determines that the temperature of the main roller 40 is stabilized after the temperature of the base material 90 falls within the threshold range, the controller 60 switches from control to adjust the temperature of the base material 90 with temperature adjustment of the main roller 40 and the adhesion force between the main roller 40 and the base material 90 to control to adjust the temperature of the base material 90 with the temperature of the main roller 40. The controller 60 controls the adhesion force with the tensile force of the base material 90 wound and conveyed by the main roller 40 or with the electrostatic force acting between the main roller 40 and the base material 90.

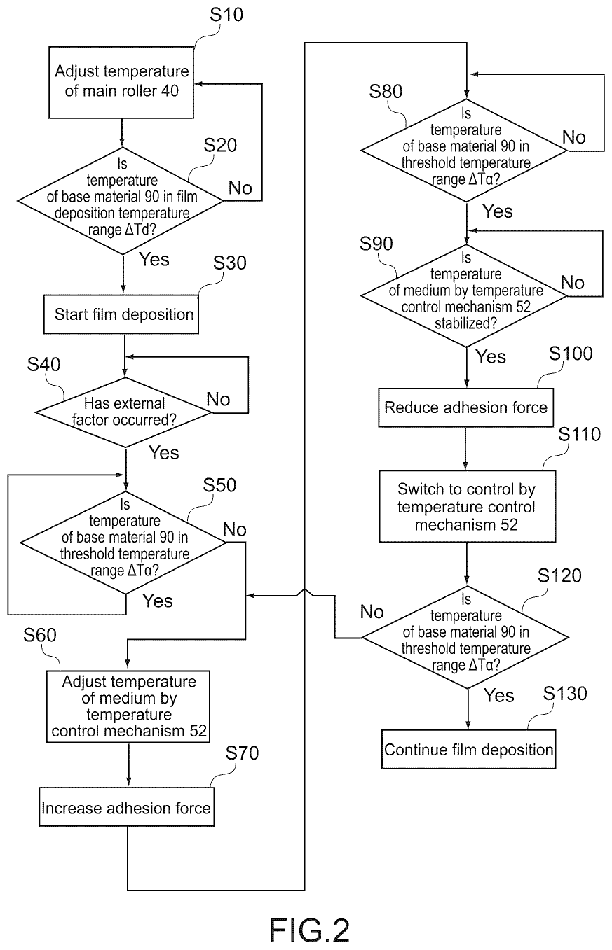

FIG. 2 is a flowchart showing an example of a vacuum treatment method according to the present embodiment. The deposition method will be specifically described in accordance with the flow shown in FIG. 2. The controller 60 automatically performs this flow.

First of all, the temperature adjustment of the main roller 40 is performed before the start of film deposition (Step S10). The temperature of the medium fed to the main roller 40 from the temperature control mechanism 52 is set to be a desired temperature so that the temperature of the base material 90 detected by the thermometer 51 becomes a desired film deposition temperature by using the above-mentioned calibration curves, for example.

Next, a determination as to whether or not the temperature of the base material 90 is in the film deposition temperature range (ΔTd) is performed (Step S20). For example, the temperature of the base material 90 detected by the thermometer 51 is sent to the controller 60. When the temperature of the base material 90 is in the film deposition temperature range (Yes), the processing shifts to next Step S30. On the other hand, when the temperature of the base material 90 is not in the film deposition temperature range (No), the temperature adjustment of the main roller 40 is continuously performed.

Next, when the temperature of the base material 90 is in the film deposition temperature range, film deposition is started (Step S30). For example, the vapor flow 21 fed from the deposition source 20 is deposited on the base material 90 and a film is formed on the base material 90.

Next, it is determined whether or not an external factor such as radiation from the heat source such as the evaporation source and a change in conveying velocity for adjusting the thickness of the film deposition film has occurred after the start of film deposition (Step S40). Here, when a change (±Δ5° C.) from the film deposition temperature on the temperature of the base material 90 detected by the thermometer 51 has occurred, it is determined that an external factor has occurred (Yes), the processing shifts to next Step S50. On the other hand, when the temperature of the base material 90 detected by the thermometer 51 has not changed from the film deposition temperature, it is determined that no external factor has occurred (No), and the film deposition is continued. It should be noted that examples of the external factor include radiation from the heat source such as the evaporation source and a change in conveying velocity for adjusting the thickness of the film deposition film.

Next, when it is determined that an external factor has occurred after the start of film deposition, it is determined whether or not the temperature of the base material 90 is in a threshold temperature range (ΔTα) (Step S50). Here, when the temperature of the base material 90 is not in the threshold temperature range (No), the processing shifts to next Step S60. On the other hand, when the temperature of the base material 90 is in the threshold temperature range (Yes), it is determined whether or not the temperature of the base material 90 is in the threshold temperature range while continuing the film deposition.

Next, when the temperature of the base material 90 is not in the threshold temperature range, the temperature control mechanism 52 adjusts the temperature of the medium (Step S60). For example, the temperature of the medium fed to the main roller 40 from the temperature control mechanism 52 is set to be the predetermined temperature so that the temperature of the base material 90 detected by the thermometer 51 falls within the threshold temperature range.

For example, when the temperature of the base material 90 exceeds an upper limit (T max) of the threshold temperature range, the temperature of the medium fed to the main roller 40 from the temperature control mechanism 52 is set to be lowered. On the other hand, when the temperature of the base material 90 drops below a lower limit (T min) of the threshold temperature range, the temperature of the medium fed to the main roller 40 from the temperature control mechanism 52 is set to be increased.

It should be noted that when attempting to control the temperature of the main roller 40 with only the temperature of the medium fed to the main roller 40, the temperature of the main roller 40 is not set to be a desired temperature for a while due to a difference in heat capacity between the medium and the main roller 40 in some cases. Thus, in the present embodiment, in order to reduce the time for which the temperature of the main roller 40 reaches the desired temperature, control is performed so that the temperature of the base material 90 falls within the threshold temperature range by increasing the adhesion force between the base material 90 and the main roller 40 (Step S70), increasing the thermal conductivity between the base material 90 and the main roller 40 while the temperature of the medium is set to be the predetermined temperature.

The adhesion force between the base material 90 and the main roller 40 is adjusted by controlling the position of at least either the auxiliary roller 43 or 44 via the moving mechanism or controlling the bias potential applied to the main roller 40. For example, when the temperature of the base material 90 exceeds the upper limit (Tₘₐₓ) of the threshold temperature range or drops below the lower limit (Tₘᵢₙ), the adhesion force between the base material 90 and the main roller is set to be increased. That is, control is performed so that the temperature of the base material 90 rapidly falls within the threshold temperature range by increasing the thermal conductivity between the base material 90 and the main roller 40.

Next, it is determined whether or not the temperature of the base material 90 is the threshold temperature range (ΔTα) after the adhesion force between the base material 90 and the main roller is increased (Step S80). Here, when the temperature of the base material 90 is in the threshold temperature range (Yes), the processing shifts to next Step S90. On the other hand, when the temperature of the base material 90 is not in the threshold temperature range (No), it is determined whether or not the temperature of the base material 90 is in the threshold temperature range while continuing the film deposition.

Next, when the temperature of the base material 90 is in the threshold temperature range, a determination as to whether or not the medium temperature in adjustment of the medium temperature by the temperature control mechanism 52 is stabilized is performed (Step S90). Here, when the medium temperature by the temperature control mechanism 52 is stabilized (Yes), the processing shifts to next Step S100. On the other hand, when the medium temperature by the temperature control mechanism 52 is not stabilized (No), a determination as to whether or not the medium temperature by the temperature control mechanism 52 is stabilized is performed again while continuing the film deposition. Whether or not the medium temperature by the temperature control mechanism 52 is stabilized is determined based on whether or not a temperature change rate ΔTm/Δt (t denotes a time (mins)) of the medium temperature Tm per unit time is in a desired range.

Next, when the medium temperature by the temperature control mechanism 52 is stabilized, the adhesion force between the base material 90 and the main roller 40 is reduced (Step S100). It is because the film deposition is continued in a state in which excess load is applied on the base material 90 if the film deposition is continued while increasing the adhesion force between the base material 90 and the main roller 40. For example, the film deposition is continued in a state in which a strong tensile force is applied on the base material 90 when the tensile force is increased. For example, the base material 90 adhering to the main roller 40 is peeled off from the main roller 40 maintaining a strong adhesion force when an electrostatic adhesion force is increased. Moreover, such load can adversely affect not only the base material 90 but also the film formed on the base material 90.

Therefore, in the present embodiment, the adhesion force between the base material 90 and the main roller 40 is reduced after the medium temperature by the temperature control mechanism 52 is stabilized. For example, the position of the auxiliary roller 43 or 44 is returned to the original position (the position when the film deposition is started) or the bias potential applied to the main roller 40 is returned to the original bias potential (the bias potential when the film deposition is started).

Accordingly, the control to adjust the temperature of the base material 90 with the temperature adjustment of the main roller 40 and the adhesion force between the main roller 40 and the base material 90 is switched to the control to adjust the temperature of the base material 90 with the temperature of the main roller 40 (Step S110).

Subsequently, it is determined whether or not the temperature of the base material 90 is in the threshold temperature range (ΔTα) (Step S120). Here, when the temperature of the base material 90 is in the threshold temperature range (Yes), the film deposition is continued. That is, the film deposition is continued in a state in which the load on the base material 90 is released. On the other hand, when the temperature of the base material 90 is not in the threshold temperature range (No), the processing returns to Step S60 and the routine of Steps S60 to S120 is repeated.

It should be noted that when the base material 90 is a PET resin, the film deposition temperature range of the base material 90 is set within a range from −50° C. to 100° C. The threshold temperature range is set within the set temperature of the main roller ±10° C. Moreover, when the base material 90 is metal, the film deposition temperature range of the base material 90 is set within a range from −50° C. to 180° C. The threshold temperature range is set within the set temperature of the main roller ±10° C. Moreover, ΔTm/Δt is set to be 1° C./min or less.

Moreover, regarding adjustment of the adhesion force, an upper limit value of the tensile force may be set for adjustment of the tensile force by the auxiliary roller 43 or 44 for example when the base material 90 is a metal material. For example, when the base material 90 is a metal material, the base material 90 can have a crack when the tensile force applied on the base material 90 exceeds a threshold (upper limit value). Therefore, an upper limit value of the tensile force may be set for adjustment of the tensile force by the auxiliary roller 43 or 44. For example, the upper limit value is 0.06 N/mm base material width/μm thickness. When the controller 60 determines that the tensile force exceeds the upper limit value, the controller 60 is capable of switching the adjustment of the adhesion force of the base material 90 with the tensile force to the adjustment of the adhesion force of the base material 90 with the electrostatic adhesion force.

Hereinabove, the embodiments of the present invention have been described, though the present invention is not limited to those embodiments and various modifications can be made as a matter of course. The respective embodiments are not limited to the aspects in which they are independently carried out and can be combined as long as it is technically possible.

What is claimed is:

1. A vacuum treatment apparatus, comprising:
a wind-off roller that pays out a base material having a film deposition surface and a non-film deposition surface opposite to the film deposition surface;
a wind roller configured to wind the base material;
a main roller that is provided between the wind-off roller and the wind roller in a conveying direction in which the base material is conveyed, has an outer circumferential surface that is held in contact with the non-film deposition surface, and is configured to wind and convey the base material;
a deposition source that faces the outer circumferential surface of the main roller that is held in contact with the non-film deposition surface;
an auxiliary roller that is provided at least either between the wind-off roller and the main roller or between the wind roller and the main roller in the conveying direction, configured to guide conveyance of the base material and adjust a tensile force of the base material wound and conveyed by the main roller;
a thermometer configured to measure a temperature of the base material wound and conveyed by the main roller;
a power source configured to apply a bias potential to the main roller;
a temperature control mechanism configured to adjust a temperature of the main roller; and
a controller configured to control the auxiliary roller, the thermometer, the power source, and the temperature control mechanism, wherein
the controller is configured to
detect the temperature of the base material wound and conveyed by the main roller,
start film deposition to form a film deposition material on the base material when the temperature of the base material is in a film deposition temperature range,
adjust the temperature of the main roller so that the temperature of the base material falls within the threshold range and adjust an adhesion force between the main roller and the base material when the temperature of the base material is out of a threshold range after starting film deposition on the base material, and
continue the film deposition of the film deposition material on the base material with the temperature of the base material in the film deposition temperature range.

2. The vacuum treatment apparatus according to claim 1, wherein
the controller is configured to switch from control to adjust the temperature of the base material with temperature adjustment of the main roller and the adhesion force between the main roller and the base material to control to adjust the temperature of the base material with the temperature of the main roller when the temperature of the main roller is stabilized after the temperature of the base material falls within the threshold range.

3. The vacuum treatment apparatus according to claim 1, wherein
the controller is configured to control the adhesion force with the tensile force of the base material wound and conveyed by the main roller or with an electrostatic force acting between the main roller and the base material.

4. A vacuum treatment method, comprising:
by use of a vacuum treatment apparatus including
a wind-off roller that pays out a base material having a film deposition surface and a non-film deposition surface opposite to the film deposition surface,
a wind roller that winds the base material,
a main roller that is provided between the wind-off roller and the wind roller in a conveying direction in which the base material is conveyed, has an outer circumferential surface that is held in contact with the non-film deposition surface, and winds and conveys the base material,
a deposition source that faces the outer circumferential surface of the main roller that is held in contact with the non-film deposition surface,
an auxiliary roller that is provided at least either between the wind-off roller and the main roller or between the wind roller and the main roller in the conveying direction, guides conveyance of the base material, and adjusts a tensile force of the base material wound and conveyed by the main roller;
a thermometer that measures a temperature of the base material wound and conveyed by the main roller,
a power source that applies a bias potential to the main roller, and
a temperature control mechanism that adjusts a temperature of the main roller, detecting the temperature of the base material wound and conveyed by the main roller;
starting film deposition to form a film deposition material on the base material when the temperature of the base material is in a film deposition temperature range;
adjusting the temperature of the main roller so that the temperature of the base material falls within the threshold range and adjusts an adhesion force between the main roller and the base material when the temperature of the base material is out of a threshold range after starting film deposition on the base material; and
continuing the film deposition of the film deposition material on the base material with the temperature of the base material in the film deposition temperature range.

5. The vacuum treatment method according to claim 4, further comprising
switching from control to adjust the temperature of the base material with temperature adjustment of the main roller and the adhesion force between the main roller and the base material to control to adjust the temperature of the base material with the temperature of the main roller when the temperature of the main roller is stabilized after the temperature of the base material falls within the threshold range.

6. The vacuum treatment method according to claim 4, further comprising
controlling the adhesion force with the tensile force of the base material wound and conveyed by the main roller or with an electrostatic force acting between the main roller and the base material.
